(19) United States
(12) Patent Application Publication
(10) Pub. No.: US 2009/0315604 A1
(43) Pub. Date: Dec. 24, 2009

(54) CLOCK SIGNAL GENERATION APPARATUS AND DISCRETE-TIME CIRCUIT

(75) Inventors: Taiji AKIZUKI, Miyagi (JP); Masahiko SAGISAKA, Kyoto (JP); Hisashi ADACHI, Osaka (JP)

Correspondence Address: RATNERPRESTIA, P.O. BOX 980, VALLEY FORGE, PA, 19482, US

(73) Assignee: Panasonic Corporation, Osaka (JP)

(21) Appl. No.: 12/483,640

(22) Filed: Jun. 12, 2009

(30) Foreign Application Priority Data
Jun. 23, 2008 (JP) 2008-162870

(51) Int. Cl. H03K 3/00

(52) U.S. Cl. 327/259

(57) ABSTRACT

In a clock signal generation apparatus, a clock signal delay calculation section has a delay detection circuit for monitoring the delay characteristics of the variable delay circuits of a clock signal generation circuit due to external variation factors and calculates the delay amounts of N-phase clock signals, and a clock signal delay control section varies the delay amounts of the variable delay circuits on the basis of delay variation data, external variation factors being used as parameters thereof, stored in a delay variation data section and the calculated delay amounts of the N-phase clock signals. In the case that, for example, clock signals required for a discrete-time circuit have changed due to external variation factors, such as power supply voltage and environmental temperature, the non-overlap times and the duty ratios of the clock signals required for the discrete-time circuit can be set to optimal values.

### BACKGROUND OF THE INVENTION

The present invention relates to a clock signal generation apparatus for use in discrete-time circuits, etc., operating at high speed.

In recent years, as data transfer speed becomes higher due to broadbandization in communication system, a discrete-time (hereafter simply referred to as DT) circuit typified by a delta-sigma analog/digital converter (ΔΣ AD converter) is requested to operate at higher speed. Because of this request for higher speed, the operation timing of a clock signal has become very severe.

FIG. 17 is a circuit diagram showing an example of a switched-capacitor (hereafter simply referred to as SC) integrator for use in a conventional ΔΣ AD converter, etc. The SC integrator shown in FIG. 17 contains four switches (hereafter simply referred to as SW) 41a, 41b, 41c and 41d, two capacitors 42a and 42b, and an operational amplifier 43. The SW 41a performs ON/OFF operation depending on the clock timing of a clock signal Φ1, and the SW 41b performs ON/OFF operation depending on the clock timing of a clock signal Φ1D obtained by delaying the clock signal Φ1. Furthermore, the SW 41c performs ON/OFF operation depending on the clock timing of a clock signal Φ2, and the SW 41d performs ON/OFF operation depending on the clock timing of a clock signal Φ2D obtained by delaying the clock signal Φ2.

FIG. 18 is a waveform diagram showing the clock timings of the clock signals Φ1, Φ1D, Φ2 and Φ2D. As shown in FIG. 18, the clock timings of the clock signals Φ1 and Φ1D (in-phase CLK) are in phase with that of an input signal, and the clock timings of the clock signals Φ2 and Φ2D (anti-phase CLK) are in anti-phase with that of the input signal. In the H-level zones of the clock timings of the in-phase CLK Φ1 and Φ1D, the SW 41a and the SW 41b become ON, and the capacitor 42a is charged by the input signal (a charging period). At this time, the SW 41c and SW 41d are OFF.

Next, when the clock timings of the in-phase CLK Φ1 and Φ1D become L level, the SW 41a and the SW 41b become OFF, and the charging of the capacitor 42a is completed.

Next, in the H-level zones of the clock timings of the anti-phase CLK Φ2 and Φ2D, the SW 41c and the SW 41d become ON, and the charge stored in the capacitor 42a is transferred to the capacitor 42b (a discharging period). Hence, the SC integrator outputs a signal obtained by integrating the input signal. However, if the clock timings of the anti-phase CLK Φ2 and Φ2D become H level before the clock timings of the in-phase CLK Φ1 and Φ1D become L level, not only the capacitor 42a that is intended to be charged by the input signal but also the capacitor 42b is charged simultaneously. If the H-level zones of the clock timings of the in-phase CLK Φ1 and Φ1D overlap with the H-level zones of the clock timings of the anti-phase CLK Φ2 and Φ2D as described above, the SC integrator does not operate properly. Hence, as shown in the waveform diagram of FIG. 18, for the purpose of preventing the rising or falling timings of the clock signals Φ1, ΦD, Φ2 and Φ2D from becoming H level or L level simultaneously, non-overlap clock signals having a non-overlap time (Δt) between the rising or falling timing of one of the clock signals Φ1, Φ1D, Φ2 and Φ2D and the rising or falling timing of another clock signal next thereto are required.

Generally speaking, the phenomenon in which the charge of the stray capacitance stored in a switch is discharged when the switch is turned OFF is generally referred to as charge injection. For the purpose of reducing the effect of the charge due to this charge injection to the integrator, the SW 41a (Φ1) directly connected to the integrator is required to be turned OFF earlier than the SW 41b (Φ1D). Similarly, the SW 41c (Φ2) is required to be turned OFF earlier than the SW 41d (Φ2D).

Since a delay timing is generally generated using a delay device or the like, the non-overlap time fluctuates significantly due to the effect of variations in power supply voltage and environmental temperature. For this reason, in some cases, the non-overlap zone is lost, or the non-overlap zone becomes too long and the H-level zones of the clock timings of the clock signals Φ1, Φ1D, Φ2 and Φ2D become short. In the case that the non-overlap zone is lost, there occurs a problem that the SC integrator malfunctions as described above. Furthermore, in the case that the H-level zones of the clock timings of the clock signals Φ1, Φ1D, Φ2 and Φ2D become short, since the charging of the capacitor 42a using the input signal is performed in the H-level zones of the clock timings of the in-phase CLK Φ1 and Φ1D and the integration is performed in the H-level zones of the clock timings of the anti-phase CLK Φ2 and Φ2D, the circuit components including the operational amplifier 43 are required to be operated at higher speed because the H-level zones are short. Hence, the conventional SC integrator has a problem of causing increase in power consumption and circuit area.

Furthermore, in the case that the duty ratio of the in-phase CLK Φ1 and Φ1D being in phase with the input signal is different from the duty ratio of the anti-phase CLK Φ2 and Φ2D being in anti-phase with the input signal, a deviation occurs in the H-level zones of the in-phase CLK and the anti-phase CLK. For this reason, in the case that the charging time of the capacitor 42a charged by the input signal is insufficient, the switches are required to be operated at higher speed. Conversely, in the case that the integration time of the integrator is insufficient, the circuit components including the operational amplifier 43 are required to be operated at higher speed. As described above, the fluctuations in the duty ratios of the clock signals output from the clock signal generation apparatus have partly caused deterioration in the performance of the SC integrator.

Consequently, in a DT circuit, such as a ΔΣ AD converter, it is important to have optimal non-overlap clock signals being characterized in that a non-overlap time is obtained securely, that the H-level zones of the clock signals are set as long as possible, and that the duty ratios of the output signals thereof are adjusted to the same value.

For the purpose of solving the above-mentioned problems, a clock signal generator capable of adjusting the non-overlap time depending on the change in operation environment has been proposed (for example, refer to Japanese Patent Application Laid-open Publication No. 2002-108492).

FIG. 19 is a block diagram showing the configuration of a two-phase clock signal generation apparatus serving as a conventional non-overlap clock signal generator disclosed in Japanese Patent Application Laid-open Publication No. 2002-108492.

This conventional two-phase clock signal generation apparatus will be described briefly below referring to the block diagram of FIG. 19.

The two-phase clock signal generation apparatus 101 shown in FIG. 19 has a machine clock signal output section 102; a control circuit section 103 composed of a CPU; a storage circuit section 105 in which adjustment data for adjusting the non-overlap time of two-phase clock signals is stored; and a two-phase clock signal generation section 104 for generating the two-phase clock signals.

The control circuit section 103 reads appropriate data from the storage circuit section 105 in which adjustment data for adjusting the non-overlap time of the two-phase clock signals is stored and then outputs setting data to the two-phase clock signal generation section 104, depending on the sensor signals output from a temperature sensor 106 and a voltage sensor 107 for detecting operation environment. The two-phase clock signal generation section 104 is configured so that the overlap time between the A-phase clock signal and the B-phase clock signal thereof can be set variably on the basis of the setting data supplied from the control circuit section 103. In the two-phase clock signal generation apparatus 101 configured as described above, the non-overlap time is adjusted.

FIG. 20 is a circuit diagram showing the configuration of the two-phase clock signal generation section 104 in the two-phase clock signal generation apparatus 101 shown in FIG. 19, partly shown in block shape. As shown in FIG. 20, in the two-phase clock signal generation section 104, the machine clock signal MCK output from the machine clock signal output section 102 is converted into a signal IMCK using an inverter gate 108 and the input to one of the input terminals of a first OR gate 109. Furthermore, the machine clock signal MCK is directly input to one of the input terminals of a second OR gate 110.

The output signal (OR1) of the first OR gate 109 is output as the B-phase clock signal via an inverter gate 111. In addition, the B-phase clock signal is converted into a delayed B-phase clock signal (B-d) that is delayed using a second delay control section (delay detection circuit section) 112b and input to the other input terminal of the second OR gate 110. On the other hand, the output signal (OR2) of the second OR gate 110 is output as the A-phase clock signal via an inverter gate 113. Furthermore, the A-phase clock signal is converted into a delayed A-phase clock signal (A-d) that is delayed using a first delay control section (delay detection circuit section) 112a and input to the other input terminal of the first OR gate 109.

FIG. 21 is a circuit diagram showing the configuration of the first delay control section 112a, partly shown in block shape. Since the first delay control section 112a and the second delay control section 112b have the same configuration, the configuration of the first delay control section 112a is described below, and the description of the second delay control section 112b is omitted.

In the first delay control section 112a, multi-stage delay buffers 114, each stage formed of two inverter gates 114a and 114b connected in series, are connected in series. In the first delay control section 112a, the propagation delay time in one single delay buffer 114 is used as one unit of the delay time for adjustment. Furthermore, a switch 115 is provided between the input terminal of the first-stage delay buffer 114 and the output terminal of the first delay control section 112a. Moreover, one switch 115 is provided between the output terminal of each of the delay buffers 114 and the output terminal of the first delay control section 112a. The ON/OFF operation of each of the switches 115 is controlled by the output signal of a decoder 116. The decoder 116 decodes the setting data output from the control circuit section 103 and outputs a control signal for turning ON one of the switches 115. As described above, the two-phase clock signal generation section 104 controls the delay values of the first and second delay control sections 112a and 112b on the basis of the setting data output from the control circuit section 103, thereby adjusting the non-overlap time between the A-phase clock signal and the B-phase clock signal.

In the conventional two-phase clock signal generation apparatus shown in FIG. 19, the variations in the delay of the delay detection circuit section constituting the two-phase clock signal generation section due to external fluctuation factors, such as power supply voltage and environmental temperature, are adjusted on the basis of the preset adjustment data so that the non-overlap time is maintained constant. However, since the characteristics of individual discrete-time (DT) circuits are different due to external fluctuation factors, such as power supply voltage and environmental temperature, and the non-overlap time required for each of the DT circuits varies differently, the conventional clock signal generation apparatus has a problem that the apparatus cannot accurately cope with the variations in the non-overlap time described above.

In addition, since the output load of the two-phase clock signal generation apparatus serving as a non-overlap clock signal generator varies with the variations in the stray capacitance in the DT circuit due to external fluctuation factors, such as power supply voltage and environmental temperature, the delay amount required for the non-overlap time between the in-phase CLK and the anti-phase CLK is different from the delay amount required for the non-overlap time between the in-phase CLK or between the anti-phase CLK. However, the conventional clock signal generation apparatus cannot take measures for the situation in which the delay amount required for the non-overlap time between the in-phase CLK and the anti-phase CLK is different from the delay amount required for the non-overlap time between the in-phase CLK or between the anti-phase CLK, thereby having a problem in that the respective CLK cannot be adjusted to have an optimal non-overlap time.

### SUMMARY OF THE INVENTION

An object of the present invention is to provide a clock signal generation apparatus being characterized in that, in the case that clock signals required for a DT circuit have changed and that the output load of the clock signal generation apparatus has changed due to external fluctuation factors, such as power supply voltage and environmental temperature, the non-overlap times and the duty ratios of the clock signals required for the DT circuit can be variably adjusted and set to optimal values for respective output signals.

A clock signal generation apparatus according to a first aspect of the present invention is equipped with:

a clock signal generation circuit, having n (n: a positive integer) variable delay circuits having variable delay amounts, for generating N-phase (N: a positive integer) clock signals,

a clock signal delay calculation section, having a delay detection circuit for monitoring the delay characteristics of the variable delay circuits of the clock signal generation circuit due to external variation factors, for calculating the delay amounts of the generated N-phase clock signals,

delay variation data section for previously storing the delay variation data of the non-overlap times between the respective phase output clock signals required for a discrete-time circuit to which the output clock signals from the clock signal generation circuit are supplied, and

a clock signal delay control section for varying the delay amounts of the variable delay circuits on the basis of the delay variation data, external variation factors being used as parameters thereof, stored in the delay variation data section and the delay amounts of the N-phase clock signals calculated in the clock signal delay control section. In the clock signal generation apparatus according to the first aspect configured as described above, in the case that the clock signals required for the discrete-time circuit have changed and that the output load of the clock signal generation apparatus has changed due to external variation factors, such as power supply voltage and environmental temperature, the non-overlap times and the duty ratios of the clock signals required for the discrete-time circuit can be variably adjusted and set to optimal values for respective output signals.

In the clock signal generation apparatus according to the first aspect of the present invention configured as described above, the delay variation data of the non-overlap times required for the discrete-time circuit due to external variation factors is stored previously in the delay variation data section, and the clock signal delay control section control the delay amounts of the variable delay circuits by using external variation factors, such as power supply voltage and environmental temperature, as input parameters, whereby the non-overlap times can be variably controlled to optimal values.

In addition, in the clock signal generation apparatus according to the first aspect, in the case that the output load of the clock signal generation apparatus has changed due to external variation factors, although the variation amounts of the non-overlap times between the respective output clock signals do not have the same value, since the non-overlap times varying due to external variation factors are previously stored in the delay variation data section and the clock signal delay control section separately controls the delay amounts of the variable delay circuits by using external variation factors, such as power supply voltage and environmental temperature, as input parameters, the non-overlap times can be variably controlled to optimal values regardless of the variations in the output load.

Furthermore, in the clock signal generation apparatus according to the first aspect, since the clock signal delay control section variably adjusts the non-overlap times so that the duty ratios of the output clock signals have the same value, the charging time and the discharging time of the discrete-time circuit can be optimized so as to have the same time interval. As a result, the through rate and settling performance required for the discrete-time circuit can be relieved and optimized.

A clock signal generation apparatus according to a second aspect of the present invention may be configured so that the delay detection circuit according to the above-mentioned first aspect has the same delay characteristics as the delay characteristics of the variable delay circuits due to external variation factors. In the clock signal generation apparatus according to the second aspect configured as described above, even in the case that the clock signals required for the discrete-time circuit have changed due to external variation factors, such as power supply voltage and environmental temperature, the non-overlap times and the duty ratios of the clock signals required for the discrete-time circuit can be variably adjusted for respective output signals.

A clock signal generation apparatus according to a third aspect of the present invention is configured so that the clock signal delay calculation section according to the above-mentioned first aspect calculates the non-overlap time between a reference clock signal and any one of the N-phase output clock signals output from the clock signal generation circuit. In the clock signal generation apparatus according to the third aspect configured as described above, since the clock signal delay control section controls the delay amounts of the variable delay circuits by using the outputs of the clock signal delay calculation section for calculating deviations in delay amounts between the reference clock signal supplied externally and the output clock signals as input parameters, variations in the delay amounts in the clock signal generation apparatus due to external variation factors can be corrected securely, and the non-overlap times can be variably controlled optimally.

A clock signal generation apparatus according to a fourth aspect of the present invention is configured so that the clock signal delay calculation section according to the above-mentioned first aspect calculates the non-overlap time between any two signals of the N-phase output clock signals output from the clock signal generation circuit. In the clock signal generation apparatus according to the fourth aspect configured as described above, since the variation amounts of the non-overlap times can be calculated directly from the output clock signals, the non-overlap times can be variably controlled optimally more accurately.

A clock signal generation apparatus according to a fifth aspect of the present invention is configured so that the clock signal delay control section according to the above-mentioned first aspect has hysteresis between the switching standard for increasing the delay amount and the switching standard for decreasing the delay amount in the control signals to be output to the clock signal generation circuit. In the clock signal generation apparatus according to the fifth aspect configured as described above, since the output data is not affected instantaneously even if the input parameters of the clock signal delay calculation section vary slightly due to noise contamination from the outside, the delay amount switching control for the output clock signals can be stabilized, and jitter noise occurring at the time of switching can be reduced.

A clock signal generation apparatus according to a sixth aspect of the present invention is configured so that the clock signal delay control section according to the above-mentioned first aspect averages the control signals to be output to the clock signal generation circuit with a preset average number and outputs the averaged control signal. In the clock signal generation apparatus according to the sixth aspect configured as described above, the instantaneous variations in the control signals to be output to the clock signal generation circuit can be suppressed, the delay amount switching control for the output clock signals can he stabilized, and jitter noise occurring at the time of switching can be reduced.

A clock signal generation apparatus according to a seventh aspect of the present invention is configured so that the power supply voltage according to the above-mentioned first aspect can be switched between a low-voltage mode or a high-voltage mode depending on a discrete-time circuit to which the output clock signals are supplied. In the clock signal generation apparatus according to the seventh aspect configured as described above, in the case that the non-overlap times of the N-phase clock signals do not affect the characteristics of the discrete-time circuit to which the output clock signals are supplied, in other words, in the case that the transition times required for the rising/falling of the output clock signals can be relieved, the power supply voltage of the clock signal generation apparatus can be lowered and the current consumption thereof can be reduced.

A clock signal generation apparatus according to an eighth aspect of the present invention is configured so that the clock signal delay calculation section, the clock signal delay control section and the delay variation data section according to the above-mentioned first aspect are ON/OFF controlled using control signals from the outside of the apparatus. In the clock signal generation apparatus according to the eighth aspect configured as described above, in the case that the variations in the non-overlap times and the variations in the duty ratios of the output clock signals due to external variation factors are allowable, current consumption and jitter noise caused by the clock signals can be suppressed by turning OFF the control signals.

A clock signal generation apparatus according to a ninth aspect of the present invention is configured so that the clock signal delay calculation section according to the above-mentioned first aspect has initial data serving as reference to be input to the delay detection circuit and outputs the relative variation amount between the initial data and the data output from the delay detection circuit. In the clock signal generation apparatus according to the ninth aspect configured as described above, the data in the case that the non-overlap times do not vary due to external variation factors can be set as the reference data for the clock signal delay calculation section, and fluctuations in the non-overlap times due to fluctuations in system can be improved.

A discrete-time circuit according to a tenth aspect of the present invention is equipped with the clock signal generation apparatus according to any one of the above-mentioned first to ninth aspects. The discrete-time circuit according to the tenth aspect is, for example, an analog-digital converter circuit, and is equipped with the clock signal generation apparatus according to any one of the above-mentioned first to ninth aspects in which the non-overlap times are variably adjusted depending on external variation factors. Hence, even in the case that the non-overlap times required for the discrete-time circuit have changed due to external variation factors, the discrete-time circuit is driven using the optimally adjusted non-overlap times and clock signals whose duty ratios are adjusted to have the same value. For this reason, the discrete-time circuit can be prevented from malfunctioning, and the characteristics of the circuit can be stabilized. Furthermore, in the discrete-time circuit according to the tenth aspect, the through rate and settling performance required therefor can be relieved and optimized, and the circuit provides a device being high in versatility.

The present invention can provide a clock signal generation apparatus capable of optimally controlling the non-overlap times to cope with the variations in the non-overlap times required for a discrete-time circuit due to external variation factors, such as fluctuations in power supply voltage and environmental temperature, and the variations in the non-overlap times due to the variations in the output load of the clock signal generation apparatus. In addition, by using the clock signal generation apparatus according to the present invention for a discrete-time circuit, such as an analog-digital converter, malfunction and deterioration in characteristics due to external variation factors and the like can be prevented, and it is possible to provide a highly reliable discrete-time circuit.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 is a block diagram showing the configuration of a clock signal generation apparatus according to Embodiment 1 of the present invention;

FIG. 2 is a circuit diagram showing an example of a clock signal delay calculation section in the clock signal generation apparatus according to Embodiment 1;

FIGS. 3A to 3G are waveform diagrams showing a reference clock signal (reference CLK) and output signals from the clock signal delay calculation section in the clock signal generation apparatus according to Embodiment 1;

FIG. 4 is a conceptual diagram, in the form of a graph, in which the non-overlap time of clock signals is controlled so as to be constant using the conventional delay amount controlling method;

FIG. 5 is a conceptual diagram, in the form of a graph, in which the non-overlap time of clock signals is variably controlled depending on external variation factors in the clock signal generation apparatus according to Embodiment 1;

FIG. 6 is a timing chart in the case that in-phase output clock signals and anti-phase output clock signals are scarcely affected by variations in the output load;

FIG. 7 is a timing chart in the case that in-phase output clock signals and anti-phase output clock signals are significantly affected by variations in the output load;

FIG. 8 is a block diagram showing the configuration of a clock signal generation apparatus according to Embodiment 2 of the present invention;

FIG. 9 is a circuit diagram showing an example of a clock signal delay calculation section in the clock signal generation apparatus according to Embodiment 2;

FIGS. 10A to 10F are waveform diagrams showing the reference clock signal (reference CLK), a first output clock signal Φ, and the output signals from the respective delay detection circuits of the clock signal delay calculation section in the clock signal generation apparatus according to Embodiment 2;

FIG. 11 is a block diagram showing the configuration of a clock signal generation apparatus according to Embodiment 3 of the present invention;

FIG. 12 is a circuit diagram showing an example of a clock signal delay calculation section in the clock signal generation apparatus according to Embodiment 3;

FIGS. 13A to 13F are waveform diagrams showing a third output clock signal Φ2, a second output clock signal Φ1D, and the output signals from the respective delay detection circuits of the clock signal delay calculation section in the clock signal generation apparatus according to Embodiment 3;

FIG. 14 is a circuit diagram showing an example of a clock signal delay calculation section in a clock signal generation apparatus according to Embodiment 4 of the present invention;

FIGS. 15A to 15F are waveform diagrams showing a second output clock signal Φ1D, a first output clock signal Φ1), and the output signals from the respective delay detection circuits of the clock signal delay calculation section in the clock signal generation apparatus according to Embodiment 4;

FIG. 16 is a block diagram showing the configuration of a clock signal generation apparatus according to Embodiment 5 of the present invention;

FIG. 17 is the circuit diagram showing the example of the conventional switched-capacitor integrator;

FIG. 18 is the waveform diagram showing the clock timings of clock signals in the conventional switched-capacitor integrator;

FIG. 19 is the block diagram showing the configuration of the conventional clock signal generation apparatus;

FIG. 20 is the circuit diagram showing the configuration of the two-phase clock signal generation section in the clock signal generation apparatus shown in FIG. 19, partly shown in block shape; and

FIG. 21 is the circuit diagram showing the configuration of the first delay control section shown in FIG. 20, partly shown in block shape.

It will be recognized that some or all of the Figures are schematic representations for purposes of illustration and do not necessarily depict the actual relative sizes or locations of the elements shown.

### DETAILED DESCRIPTION OF THE PREFERRED EMBODIMENTS

Preferred embodiments of a preferred clock signal generation apparatus and a discrete-time circuit equipped with the clock signal generation apparatus according to the present invention will be described below referring to the accompanying drawings. In the preferred embodiments described below, a case will be described below in which four-phase signals, i.e., in-phase clock signals (in-phase CLK) Φ1 and Φ1D in phase with a reference clock signal to be input and anti-phase clock signals (anti-phase CLK) Φ2 and Φ2D in anti-phase with the reference clock signal, are used as clock signals to be output, i.e., output signals, from the clock signal generation apparatus.

In the following embodiments, a case in which four-phase output signals are used will be described below. However, the output signals are not limited to four-phase clock signals, but the present invention includes a clock signal generation apparatus outputting multiple-phase (N-phase) clock signals. N is herein a positive integer.

### Embodiment 1

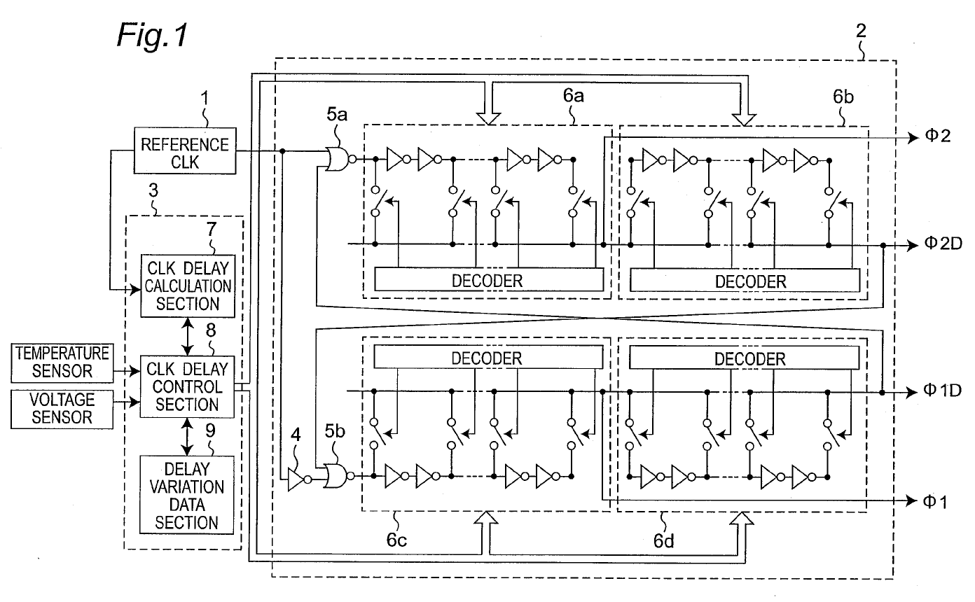

A four-phase non-overlap signal generator serving as a clock signal generation apparatus according to Embodiment 1 of the present invention will be described below referring to FIGS. 1 to 7. FIG. 1 is a block diagram showing the configuration of the clock signal generation apparatus according to Embodiment 1 of the present invention. The clock signal generation apparatus according to Embodiment 1 is equipped with a clock signal generation circuit 2 and an adjustment circuit 3 as shown in FIG. 1. In the clock signal generation apparatus according to Embodiment 1, a reference clock signal generator 1 for generating a reference clock signal (reference CLK) is not contained in the clock signal generation apparatus serving as the four-phase non-overlap clock signal generator according to Embodiment 1 but is provided outside the apparatus in an example shown in FIG. 1. However, the reference clock signal generator 1 may be contained in the clock signal generation apparatus.

The clock signal generation circuit 2 has an inverter gate 4, two NOR gates 5a and 5b and four variable delay circuits 6a to 6d, wherein the reference clock signal from the reference clock signal generator 1 is input as an input signal and four-phase signals are output.

In the clock signal generation circuit 2, the input signal, i.e., the reference clock signal, is input to one of the input terminals of the first NOR gate 5a and is also input to one of the input terminals of the second NOR gate 5b via the inverter gate 4.

The output terminal of the first NOR gate 5a is connected to the input terminals of the variable delay circuits 6a and 6b concatenated. The output from the first variable delay circuit 6a becomes a third output clock signal Φ2, and the output of the variable delay circuits 6a and 6b concatenated becomes a fourth output clock signal Φ2D. The output terminal of the second NOR gate 5b is connected to the input terminals of the variable delay circuits 6c and 6d concatenated. The output from the third variable delay circuit 6c becomes a first output clock signal Φ1, and the output of the variable delay circuits 6c and 6d concatenated becomes a second output clock signal Φ1D.

The first output clock signal Φ1 is formed by synthesizing the output of the inverter gate 4 with the fourth output clock signal Φ2D at the second NOR gate 5b and by delaying the synthesized signal using the third variable delay circuit 6c. Hence, the first output clock signal Φ1 becomes in phase with the reference clock signal, and the signal becomes High (Φ1=1) after being delayed by the delay amount of the third variable delay circuit 6c from the falling timing of the fourth output clock signal Φ2D and becomes Low (Φ1=0) after being delayed by the delay amount of the third variable delay circuit 6c from the falling timing of the reference clock signal. As a result, the non-overlap time from the falling of the fourth output clock signal Φ2D to the rising of the first output clock signal Φ1 can be controlled using the delay amount of the third variable delay circuit 6c.

Furthermore, the second output clock signal Φ1D becomes in phase with the first output clock signal Φ1 but is delayed by the delay amount of the fourth variable delay circuit 6d from the rising timing and the falling timing of the first output clock signal Φ1. As a result, the non-overlap time between the first output clock signal Φ1 and the second output clock signal Φ1D (a time in which one of the signals is turned OFF) can be controlled using the delay amount of the fourth variable delay circuit 6d.

Similarly, the third output clock signal Φ2 is formed by synthesizing the reference clock signal with the second output clock signal Φ1D at the first NOR gate 5a and by delaying the synthesized signal using the first variable delay circuit 6a. Hence, the third output clock signal Φ2 becomes in anti-phase with the reference clock signal, and the signal becomes Low (Φ2=0) after being delayed by the delay amount of the first variable delay circuit 6a from the rising timing of the reference clock signal and becomes High (Φ2=1) after being delayed by the delay amount of the first variable delay circuit 6a from the falling timing of the second output clock signal Φ1D. As a result, the non-overlap time from the falling of the third output clock signal Φ2 to the rising of the second output clock signal Φ1D can be controlled using the delay amount of the first variable delay circuit 6a.

Furthermore, the fourth output clock signal Φ2D becomes in phase with the third output clock signal Φ2 but is delayed by the delay amount of the second variable delay circuit 6b from the rising timing and the falling timing of the third output clock signal Φ2. As a result, the non-overlap time between the third output clock signal Φ2 and the fourth output clock signal Φ2D (a time in which one of the signals is turned OFF) can be controlled using the delay amount of the second variable delay circuit 6b.

As described above, in the clock signal generation apparatus serving as the four-phase non-overlap clock signal generator according to Embodiment 1, the delay amounts of the output clock signals Φ1, Φ1D, Φ2 and Φ2D can be adjusted using the variable delay circuits 6a to 6d being different from one another. For this reason, in the four-phase non-overlap clock signal generator according to Embodiment 1, non-overlap times being different from one another can be set for the respective in-phase and anti-phase clock signals.

### [Adjustment Circuit]

In the clock signal generation apparatus according to Embodiment 1, the adjustment circuit 3 for adjusting the non-overlap times will be described below.

As shown in FIG. 1, the adjustment circuit 3 is equipped with a clock signal delay calculation section (CLK delay calculation section) 7, a clock signal delay control section (CLK delay control section) 8, and a delay variation data section 9.

The clock signal delay calculation section 7 detects the variations in the delay amount of each of the variable delay circuits 6a to 6d of the clock signal generation circuit 2 due to external variation factors, such as fluctuations in power supply voltage, environmental temperature and system, and the delay amount is input to the clock signal delay control section 8. The clock signal delay control section 8 uses the delay variation data calculated by the clock signal delay calculation section 7 and the parameters of external variation factors, such as power supply voltage input externally and environmental temperature, as input data, refers to the data stored in the delay variation data section 9 and variably controls the delay amount of each of the variable delay circuits 6a to 6d.

The delay variation data section 9 of the adjustment circuit 3 according to Embodiment 1 previously stores the variation states of the non-overlap times required for a discrete-time circuit due to external variation factors, such as fluctuations in power supply voltage, environmental temperature and system; the variation states of the non-overlap times due to the variations in the delay amounts of the variable delay circuits of the clock signal generation apparatus; and the variation states of the non-overlap times due to the output load variations in the clock signal generation apparatus, as information corresponding to the respective input parameters (voltage data, temperature data, etc.) input to the clock signal delay control section 8.

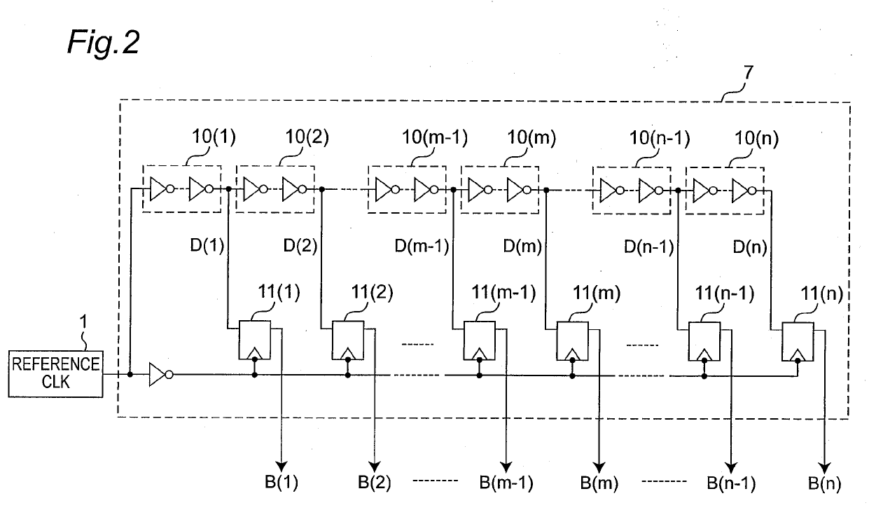

Next, the clock signal delay calculation section 7 in the adjustment circuit 3 will be described below. FIG. 2 is a circuit diagram showing an example of the clock signal delay calculation section 7. The clock signal delay calculation section 7 shown in FIG. 2 is provided to detect the variations in the delay amounts of the variable delay circuits 6a to 6d constituting the clock signal generation circuit 2 and is equipped with delay devices having the same delay characteristics as those of the delay devices constituting the variable delay circuits 6a to 6d. The clock signal delay calculation section 7 is configured so that n sets of delay detection circuits 10(1) to 10(n), each being formed of a plurality of the delay devices, are connected in series. The reference clock signal is input to the first-stage delay detection circuit 10(1), and the delay amounts of the n-sets of the delay detection circuits are added sequentially. Herein, n is a positive integer.

Furthermore, circuit connection is made so that the output signals (D(1) to (D(n)) from the respective delay detection circuits 10(1) to 10(n) are input to respective sample-hold circuits 11(1) to 11(n). The respective sample-hold circuits 11(1) to 11(n) output the signals having been input at the time as output signals B(1) to B(n) in synchronization with the falling of the reference clock signal.

The output signals B(1) to B(n) from the respective sample-hold circuits 11(1) to 11(n) are the output data of the clock signal delay calculation section 7 and indicated by output bits. In the above-mentioned configuration, as n is larger, the range in which delay calculation can be detected is increased. Furthermore, as the number of the delay devices in the respective delay detection circuits 10(1) to 10(n) is decreased, the delay amounts of the respective delay detection circuits 10(1) to 10(n) are reduced, and the resolution for detecting the delay amounts is improved.

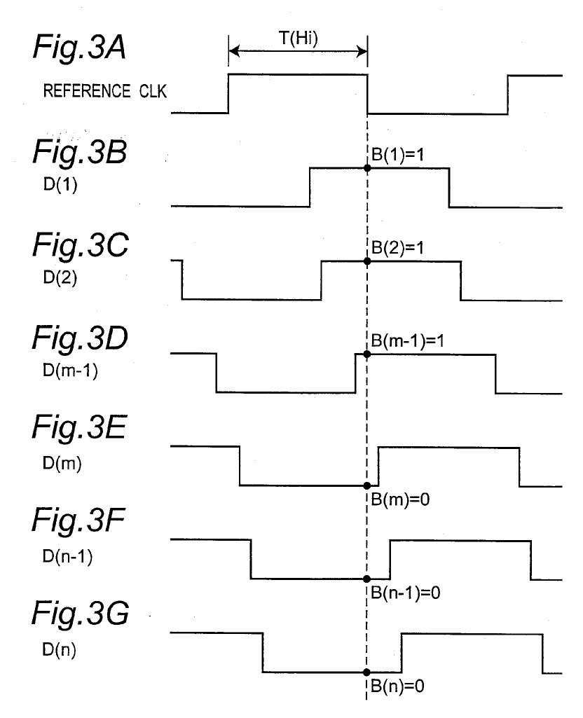

FIGS. 3A to 3G are waveform diagrams showing the reference clock signal (reference CLK) and the output signals D(1), D(2), D(m-1), D(m), D(n-1) and (D(n) output from the respective delay detection circuits 10(1), 10(2), 10(m-1), 10(m), 10(n-1) and 10(n) of the clock signal delay calculation section 7 shown in FIG. 2, indicating the relationship between the reference clock signal and the output data B(1) to B(n) held in the respective sample-hold circuits 11(1) to 11(n). In FIG. 2 and FIGS. 3D to 3E, m has a relationship of 1≦m≦n. It is assumed that each of the delay detection circuits according to Embodiment 1 is formed of one or more delay devices.

As shown in FIGS. 3A to 3G, the input reference clock signal (FIG. 3A) is sequentially delayed by the delay amounts Dt(1) to Dt(n) of the respective delay detection circuits 10(1) to 10(n) and then input to the subsequent delay detection circuits. Hence, in the case that the total of the delay amounts Dt(1) to Dt(n) of the respective delay detection circuits 10(1) to 10(n) is larger than the time interval (Hi) of the H-level zone of the reference clock signal, that is, in the case of T(Hi)<(Dt(0)+ . . . +Dt(n)), when the output signals of the respective delay detection circuits 10(1) to 10(n) are synchronized with the falling timing of the reference clock signal at the sample-hold circuits 11(1) to 11(n) and output, the output signal of one of the sample-hold circuits 11(1) to 11(n) is switched High/Low.

More specifically, as shown in the waveform diagrams of FIGS. 3B to 3G, in the output signals D(1) to D(m-1) of the delay detection circuits 10(1) to 10(n), the output data B(1) to B(m-1) held in the sample-hold circuits 11(1) to 11(m-1) become 1 (High). Furthermore, the output data B(m) to B(n) held in the sample-hold circuits 11(m) to 11(n) become 0 (Low), and the delay amounts of the respective delay detection circuits 10(1) to 10(n) are output as n-bit digital data. Since the delay detection circuits 10(1) to 10(n) according to Embodiment 1 are equipped with delay devices having the same delay characteristics as those of the variable delay circuits 6a to 6d of the clock signal generation circuit 2 shown in FIG. 1, in the case that the characteristics of the delay devices have changed due to external variation factors, such as power supply voltage and environmental temperature, and the delay amounts of the variable delay circuits 6a to 6d vary, that is, the non-overlap times vary, the delay amounts of the delay devices in the clock signal delay calculation section 7 vary similarly.

In comparison with the variations in the delay amounts of the delay detection circuits 10(1) to 10(n), since the reference clock signal generated in the reference clock signal generator 1 is a highly accurate clock signal whose rising time remains almost unchanged, in the case that the delay amounts Dt(1) to Dt(n) of the delay detection circuits 10(1) to 10(n) have changed, the variation amounts thereof are reflected to the output data B(1) to B(n). Hence, the variations in the non-overlap times due to external variation factors can be known by the output data B(1) to B(n).

### [Delay Amount Control for the Variable Delay Circuits]

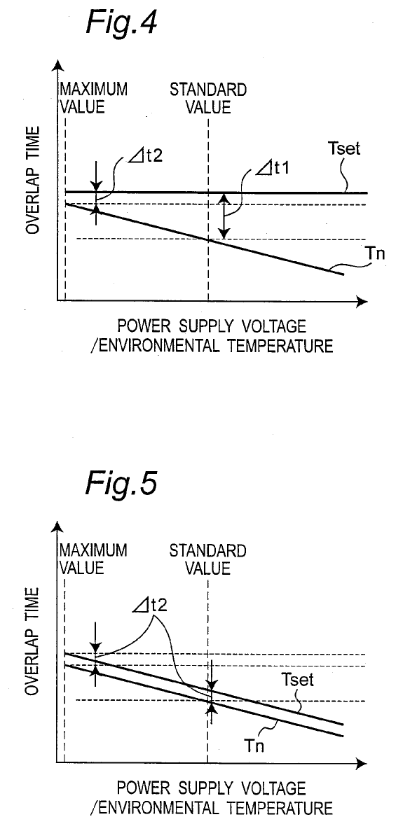

A method for controlling the delay amounts of the respective variable delay circuits 6a to 6d (see FIG. 1) of the clock signal generation circuit 2 in the clock signal generation apparatus according to Embodiment 1 of the present invention will be described below referring to FIGS. 4 and 5. FIG. 4 is a conceptual diagram, in the form of a graph, in which the non-overlap time is controlled so as to be constant regardless of external variation factors, such as power supply voltage and environmental temperature, using a conventional delay amount controlling method.

Generally speaking, in a discrete-time circuit to which clock signals are supplied, the operation characteristics, such as stray capacitances and gains, of transistor devices constituting the circuit vary due to external variation factors, such as power supply voltage and environmental temperature. For this reason, the optimal non-overlap time minimally required to operate the discrete-time circuit without malfunction will vary.

Since the conventional clock signal generation apparatus is configured so that the non-overlap time of the clock signals is set constant regardless of external variation factors, such as power supply voltage and environmental temperature, as shown in FIG. 4, the non-overlap time is set on the assumption that the non-overlap time that varies due to external variation factors has varied maximally.

As a result, for example, in the case that a standard state (standard time) in which external variation factors, such as power supply voltage and environmental temperature, are standard is used most frequently, the non-overlap time generated using the conventional clock signal generation apparatus is set longer than the optimal non-overlap time minimally required for the discrete-time circuit. In FIG. 4, “Tset” is a constant non-overlap time being set in the conventional clock signal generation apparatus. “Tn” is a minimally required non-overlap time in which the discrete-time circuit to which the clock signals are supplied does not malfunction. “Δt1” in FIG. 4 is a time obtained by subtracting the minimally required non-overlap time Tn from the preset non-overlap time Tset at the standard time and becomes a non-overlap time not necessary at the standard time. In addition, “Δt2” is a minimum overlap time obtained by subtracting the minimally required non-overlap time Tn from the preset constant non-overlap time Tset when the non-overlap time becomes maximum due to external variation factors.

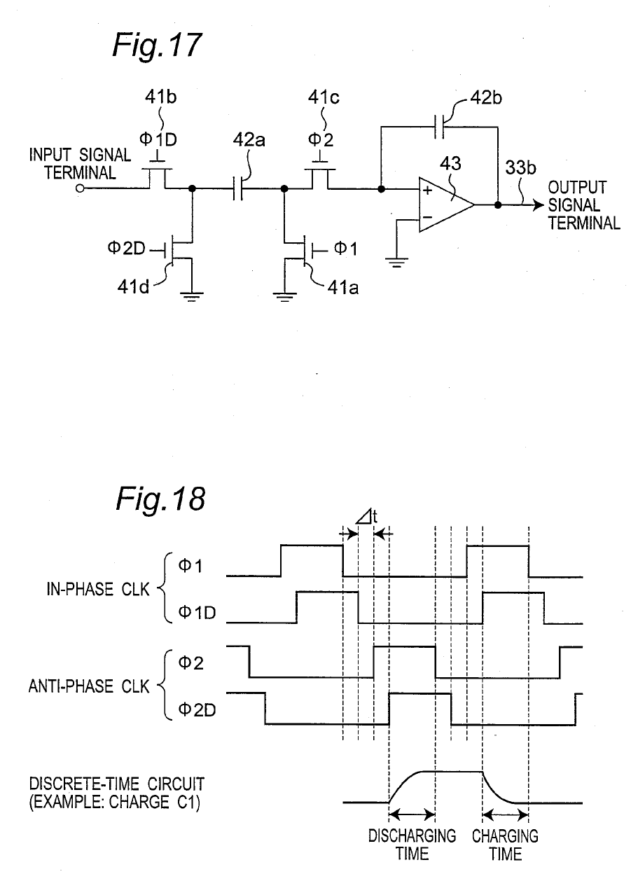

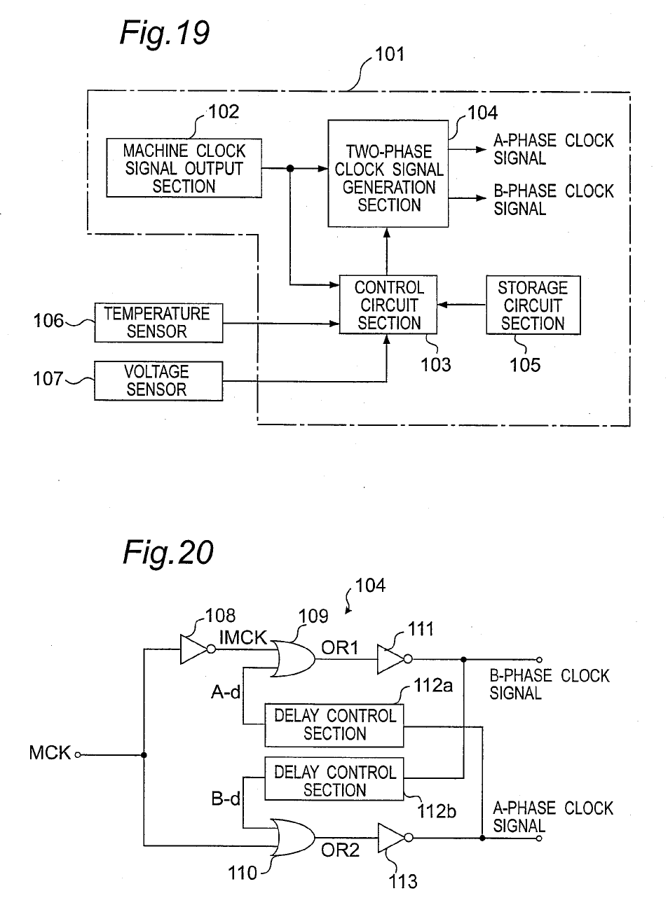

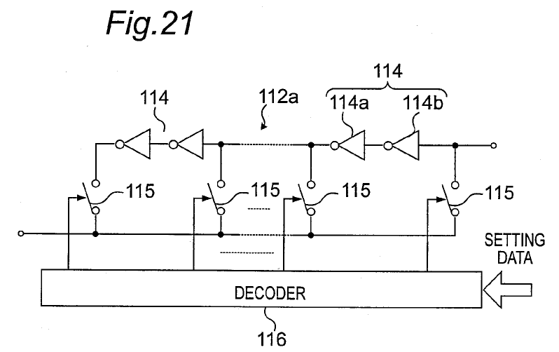

In the conventional clock signal generation apparatus described above, the unnecessary non-overlap time Δt1 becomes long at the standard time that is used frequently. Hence, the charging/discharging time of the capacitor 42a constituting the discrete-time circuit shown in FIG. 17 described above becomes short. As a result, in the discrete-time circuit shown in FIG. 17, since the charging of the capacitor 42a using the input signal is performed in the H-level zones of the clock timings of the output clock signals Φ1 and Φ1D and the integration is performed in the H-level zones of the clock timings of the output clock signals Φ2 and Φ2D, the circuit components including the operational amplifier 43 are required to be operated at higher speed because the H-level zones are short. Hence, in the case that the conventional clock signal generation apparatus is used, it has a problem of causing increase in power consumption and circuit area.

The clock signal generation apparatus according to Embodiment 1 of the present invention is intended to solve problems encountered in the above-mentioned conventional clock signal generation apparatus and is configured so as to detect the non-overlap time having varied due to external variation factors and to adjust the non-overlap time to an optimal non-overlap time at all times.

FIG. 5 is a conceptual diagram, in the form of a graph, in which the non-overlap time is variably controlled depending on external variation factors, such as power supply voltage and environmental temperature, in the clock signal generation apparatus according to Embodiment 1.

In the clock signal generation apparatus according to Embodiment 1, the non-overlap time required for the discrete-time circuit and varying depending on external variation factors, such as power supply voltage and environmental temperature, is obtained beforehand, and the obtained delay variation data is stored in the delay variation data section 9 of the adjustment circuit 3 (see FIG. 1). The delay variation data from the clock signal delay calculation section 7 and the parameters of power supply voltage input externally and environmental temperature are input to the clock signal delay control section 8 of the adjustment circuit 3. The clock signal delay control section 8 variably controls the delay amounts of the variable delay circuits 6a to 6d in the clock signal generation circuit 2 referring to the delay variation data in the delay variation data section 9.

In comparison with the case in which the non-overlap time is set constant as in the case of the conventional clock signal generation apparatus shown in FIG. 4, the clock signal generation apparatus according to Embodiment 1 variably controls the non-overlap time properly depending on external variation factors as described above. Hence, even in the case that the standard time in which external variation factors, such as environmental temperature and power supply voltage, are standard is generally used most frequently, the clock signals output from the clock signal generation apparatus can be controlled properly so as to be adapted to the optimal overlap time having a constant margin while satisfying the minimum required for the discrete-time circuit and varying depending on external variation factors.

Hence, with the clock signal generation apparatus according to Embodiment 1, in the discrete-time circuit, such as an analog-digital converter (AD converter), to which the clock signals are supplied, the charging/discharging time can be set to an maximally optimal time, and the circuit can have a configuration in which the increase in current consumption and circuit area required for the discrete-time circuit is suppressed to minimum.

Furthermore, since the stray capacitance characteristics of transistor devices, etc. constituting the discrete-time circuit vary due to external variation factors, such as fluctuations in power supply voltage, environmental temperature and system, the output load of the clock signal generation apparatus for supplying the clock signals to the discrete-time circuit also varies due to such external variation factors.

The clock signal generation apparatus according to Embodiment 1 is configured so that the delay amounts of the respective variable delay circuits 6a to 6d of the clock signal generation circuit 2 separately control the delay amount between the output clock signals Φ1 and Φ1D in phase with the reference clock signal, the delay amount between the output clock signals Φ2 and Φ2D in anti-phase with the reference clock signal or the delay amount between the in-phase output clock signals Φ1 and Φ1D and the anti-phase output clock signals Φ2 and Φ2D depending on the variations in the output load due to external variation factors. Hence, the clock signal generation apparatus according to Embodiment 1 can adjust the non-overlap times between the respective output clock signals to an optimal overlap time required for the discrete-time circuit.

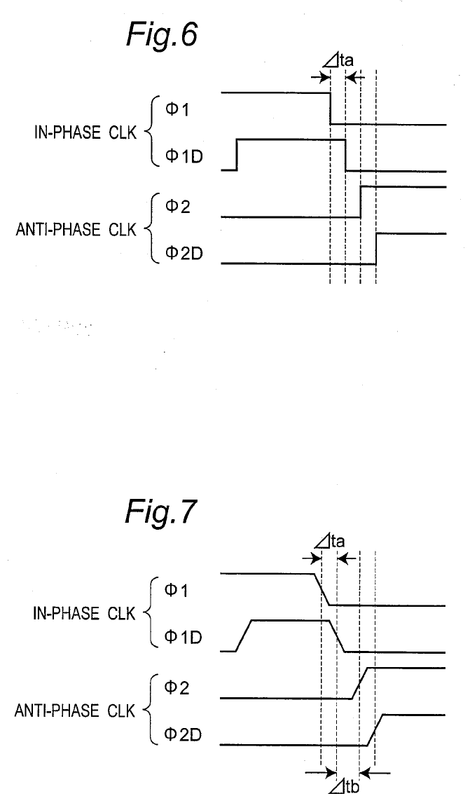

Furthermore, the variations in the non-overlap time in the case that the capacitance of the output load has varied will be described referring to timing charts shown in FIGS. 6 and 7. Herein, a case in which the delay amounts of the respective variable delay circuits 6a to 6d for generating the clock signals are constant and only the output load has varied will be described.

FIG. 6 is a timing chart in the case that the in-phase output clock signals (Φ1 and Φ1D) and the anti-phase output clock signals (Φ2 and Φ2D) are scarcely affected by the variations in the output load. Generally speaking, the transient response time required for the rising and falling of output clock signals becomes longer as the output load capacitance increases because the output load serves as a primary filter. Herein, “in the case that the signals are scarcely affected” in the timing chart shown in FIG. 6 is a case in which the transient response time is one-tenth of the non-overlap time or less.

Hence, in the case that the output load capacitance is small, the transient response time required for the rising and falling of the output clock signals can be ignored as shown in FIG. 6. For this reason, the non-overlap times between the respective output clock signals can be treated as the same time interval.

FIG. 7 is a timing chart in the case that the in-phase output clock signals (Φ1 and Φ1D) and the anti-phase output clock signals (Φ2 and Φ2D) are significantly affected by the variations in the output load. The delay devices constituting the respective variable delay circuits 6a to 6d are formed of even number of High/Low switching devices, such as inverters, and concatenated, and the delay amounts are generated depending on their operation times. In the case that the output load capacitance has increased, the High-going threshold voltage of the delay device is a voltage (>Vdd/2) close to power supply voltage Vdd, and the Low-going threshold voltage (<Vdd/2) is a voltage close to ground voltage. Hence, a deviation occurs between the High/Low-going threshold voltages of the rising timing and the falling timing as shown in FIG. 7.

As a result, since the output waveforms are just delayed between the in-phase output clock signals (Φ1 and Φ1D) or between the anti-phase output clock signals (Φ2 and Φ2D), the High/Low-going threshold voltages are the same, and the non-overlap times (Δta) become the same.

On the other hand, in the delay amount between the in-phase output clock signals (Φ1 and Φ1D) and the anti-phase output clock signals (Φ2 and Φ2D), since the output signals are delayed and inverted, the threshold voltage has a different value. As a result, the non-overlap time requires a time longer than the time in which the output waveform is just delayed. In other words, as shown in FIG. 7, the non-overlap time (Δtb) between the in-phase output clock signals (Φ1 and Φ1D) and the anti-phase output clock signals (Φ2 and Φ2D) becomes longer than the non-overlap time (Δta) between the in-phase output clock signals (Φ1 and Φ1D).

Furthermore, generally speaking, in the case that inverter gates are used as delay devices constituting a clock signal generator, since the inverter gate is formed of two different types of transistors, an n-p-n transistor and a p-n-p transistor, the charging amount is generally different from the discharging amount. For this reason, in the case that the output load capacitance is large and can be regarded as a primary filter, since the rising time and the falling time are proportional to the charging amount and the discharging amount of the inverter gate outputting the output clock signal, the rising time and the falling time do not have the same time transition but have hysteresis, and a deviation occurs between the duty ratios of the respective output clock signals.

Hence, in the clock signal generation apparatus according to Embodiment 1 of the present invention, in the case that the stray capacitances in the circuits constituting the discrete-time circuit to which the clock signals are supplied vary owing to external variation factors, such as power supply voltage and environmental temperature, and that the output load of the clock signal generation apparatus varies, the variations in the non-overlap time due to the variations in the output load are corrected using the delay variation data stored previously. The clock signal generation apparatus according to Embodiment 1 previously stores the delay variation data for changing the delay amounts of the variable delay circuits 6a to 6d depending on external variation factors, refers to the delay variation data, and controls the delay amounts of the variable delay circuits 6a to 6d in the clock delay control section 8. The clock signal generation apparatus according to Embodiment 1 configured as described above can adjust the non-overlap time between the respective output clock signals to an optimal time required for the discrete-time circuit even when the output load has changed due to external variation factors, such as power supply voltage and environmental temperature.

As a result, in the discrete-time circuit to which the four-phase clock signals having non-overlap times are supplied, the charging time and the discharging time can be set to maximum, and the circuit can have a configuration in which the increase in current consumption and circuit area required for the discrete-time circuit is suppressed to minimum.

In the clock signal generation apparatus according to Embodiment 1, a configuration example has been described in which the non-overlap times of the four-phase clock signals are detected and controlled. However, it is needless to say that the clock signal generation apparatus can be configured so that the non-overlap times of N-phase (multiple-phase) clock signals are detected and controlled by using similar technological features.

In the clock signal generation apparatus according to Embodiment 1, the clock signal delay control section 8 may be configured so as to have hysteresis between the switching standard for increasing the delay amount and the switching standard for decreasing the delay amount in the control signals to be output to the clock signal generation circuit 2. In the clock signal generation apparatus configured as described above, since the output data is not affected instantaneously even if the input parameters of the clock signal delay calculation section 7 vary slightly due to noise contamination from the outside, the delay amount switching control for the output clock signals can be stabilized, and jitter noise occurring at the time of switching can be reduced.

In addition, the clock signal generation apparatus according to Embodiment 1 may be configured so that the clock signal delay control section 8 averages the control signals to be output to the clock signal generation circuit 2 with a preset average number and outputs the averaged control signal. In the clock signal generation apparatus configured as described above, the instantaneous variations in the control signals to be output to the clock signal generation circuit 2 can be suppressed, the delay amount switching control for the output clock signals can be stabilized, and jitter noise occurring at the time of switching can be reduced.

Furthermore, the clock signal generation apparatus according to Embodiment 1 may be configured so that the clock signal delay calculation section 7, the clock signal delay control section 8 and the delay variation data section 9 are ON/OFF controlled using control signals from the outside of the apparatus. In the clock signal generation apparatus configured as described above, in the case that the variations in the non-overlap times and the variations in the duty ratios of the output clock signals due to external variation factors are allowable, current consumption and jitter noise caused by the clock signals can be reduced by turning OFF the control signals from the outside of the apparatus.

Moreover, the clock signal generation apparatus according to Embodiment 1 may be configured so that the clock signal delay calculation section 7 has initial data serving as reference to be input to the first-stage delay detection circuit 10(1) and outputs the relative variation amount between the initial data and the data output from the delay detection circuits 10(1) to 10(n). In the clock signal generation apparatus configured as described above, the data in the case that the non-overlap times do not vary due to external variation factors can be set as the reference data for the clock signal delay calculation section 7, and fluctuations in the non-overlap times due to fluctuations in system can be improved.

Besides, by equipping the clock signal generation apparatus according to Embodiment 1 serving as a clock signal generator for variably adjusting the non-overlap times depending on external variation factors with a discrete-time circuit, this discrete-time circuit, such as an analog-digital converter circuit, is driven using non-overlap times optimally adjusted to cope with variations in the non-overlap times required for the discrete-time circuit due to external variation factors and using clock signals whose duty ratios are adjusted to have the same value. Hence, the discrete-time circuit can be prevented from malfunctioning, and the characteristics of the circuit can be stabilized. In addition, in the discrete-time circuit, the through rate and settling performance required therefor can be relieved, and the circuit provides a device being high in versatility.

As described above, the clock signal generation apparatus according to Embodiment 1 serves as an N-phase non-overlap clock signal generator capable of optimally controlling the non-overlap times to cope with the variations in the non-overlap times required for the discrete-time circuit due to external variation factors, such as fluctuations in power supply voltage, environmental temperature and system, and to cope with the variations in the non-overlap times due to the variations in the output load of the clock signal generation apparatus. In addition, by using the clock signal generation apparatus according to Embodiment 1 for a discrete-time circuit, such as an analog-digital converter, malfunction and deterioration in characteristics due to external variation factors and the like can be prevented, and it is possible to provide a highly reliable discrete-time circuit.

### Embodiment 2

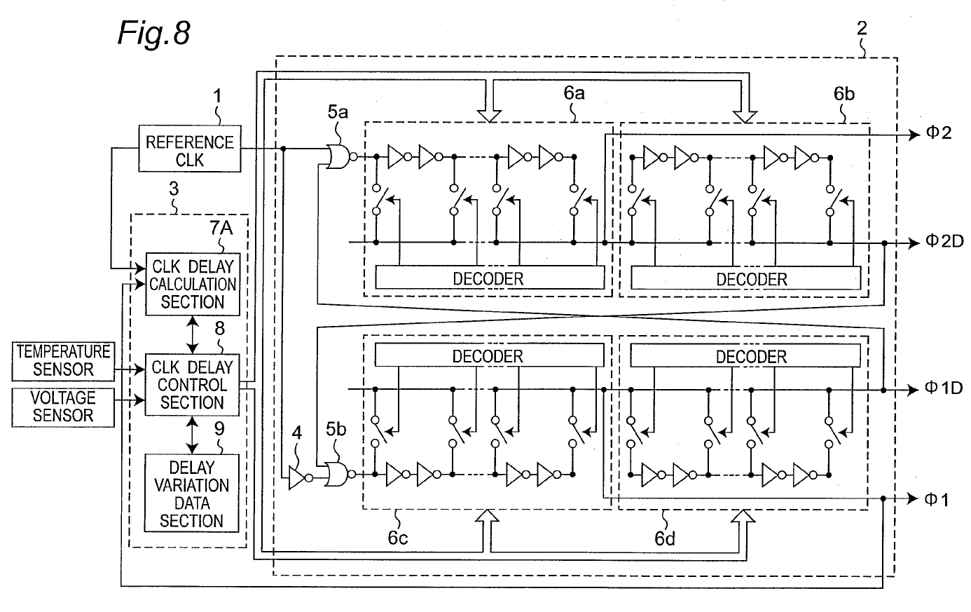

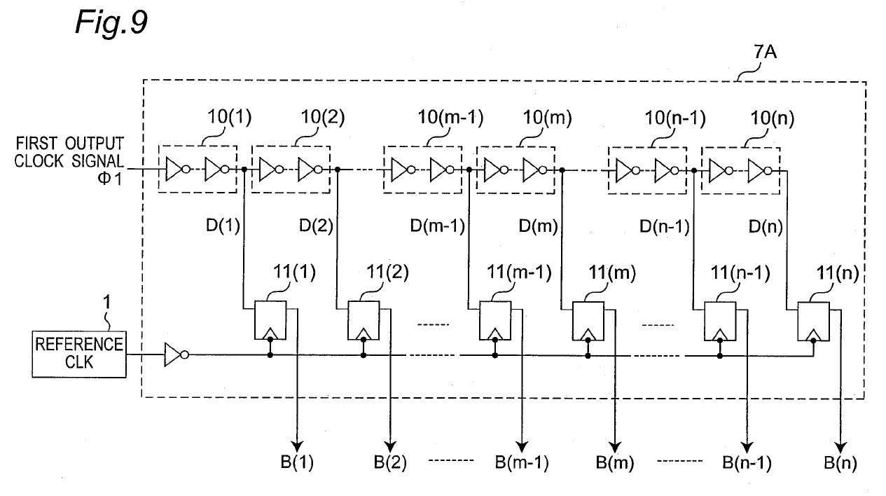

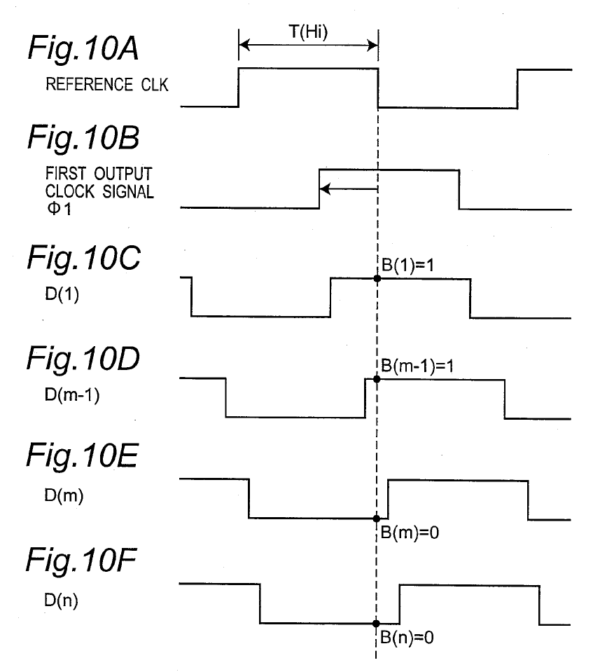

A four-phase non-overlap clock signal generator serving as a clock signal generation apparatus according to Embodiment 2 of the present invention will be described below referring to FIGS. 8 and 9 and waveform diagrams of FIGS. 10A to 10F. FIG. 8 is a block diagram showing the configuration of the clock signal generation apparatus according to Embodiment 2 of the present invention. As shown in FIG. 8, the clock signal generation apparatus according to Embodiment 2 is equipped with the clock signal generation circuit 2 and the adjustment circuit 3 as in the case of the clock signal generation apparatus according to Embodiment 1 shown in FIG. 1 described above.

The clock signal generation apparatus according to Embodiment 2 differs from the clock signal generation apparatus according to Embodiment 1 described above in that the first output clock signal Φ1 is input to the clock signal delay calculation section 7A of the adjustment circuit 3 and that the delay amount of the first output clock signal Φ1 is calculated instead of that of the reference clock signal. Hence, in the description of the clock signal generation apparatus according to Embodiment 2, the configuration and operation of the clock signal delay calculation section 7A will be described. Since the configurations and operations of the other components are the same as those of the clock signal generation apparatus according to Embodiment 1, the description in Embodiment 1 is applied, and the descriptions of the other components are omitted in the description of Embodiment 2.

FIG. 9 is a circuit diagram showing an example of the clock signal delay calculation section 7A. The clock signal delay calculation section 7A shown in FIG. 9 is provided to detect the variations in the delay amounts of the variable delay circuits 6a to 6d constituting the clock signal generation circuit 2 due to external variation factors. Hence, the clock signal delay calculation section 7A is equipped with delay devices having the same delay characteristics as those of the delay devices constituting the variable delay circuits 6a to 6d. The clock signal delay calculation section 7A is configured so that n sets of delay detection circuits 10(1) to 10(n), each being formed of a plurality of the delay devices, are connected in series. The first output clock signal Φ1 is input to the first-stage delay detection circuit 10(1), and the delay amounts of the subsequent delay detection circuits 10(2) to 10(n) are added sequentially.

Furthermore, circuit connection is made so that the output signals (D(1) to (D(n)) from the respective delay detection circuits 10(1) to 10(n) are input to the respective sample-hold circuits 11(1) to 11(n). The respective sample-hold circuits 11(1) to 11(n) output the delay value (1 or 0) of the first output clock signal Φ1 having been input at the time as n-bit output data B(1) to B(n) in synchronization with the falling of the reference clock signal. Herein, “n” is a positive integer.

FIGS. 10A to 10F are waveform diagrams showing the reference clock signal (reference CLK) (FIG. 10A), the first output clock signal Φ1 (FIG. 10B), and the output signals D(1), D(m-1), D(m) and (D(n) output from the respective delay detection circuits 10(1), 10(m-1), 10(m) and 10(n) of the clock signal delay calculation section 7A. Herein, “m” is a positive integer and has a relationship of 1≦m≦n. In addition, FIGS. 10C to 10F show examples of output data B(1), B(m-1), B(m) and B(n) that are held in the respective sample-hold circuits 11(1), 11(m-1), 11(m) and 11(n) in synchronization with the falling of the reference clock signal.

As shown in FIGS. 10A to 10F, in the adjustment circuit 3 according to Embodiment 2, since the first output clock signal Φ1 is used as the input signal for detecting the delay amounts, in the output data B(1) to B(n) of the sample-hold circuits 11(1) to 11(n), output data becomes High (for example, B(m-1)=1) in the delay detection circuits up to the delay detection circuit 10(m-1) indicating the total delay amount that is smaller than the time interval between the falling timing of the reference clock signal and the rising timing of the first output clock signal Φ1. Furthermore, the output data becomes Low (for example, B(m)=0) in the delay detection circuits in and after the delay detection circuit 10(m) indicating the total delay amount that is larger than the time interval between the falling timing of the reference clock signal and the rising timing of the first output clock signal Φ1.

For this reason, if the rising of the first output clock signal Φ1 changes due to external variation factors and the non-overlap times vary, the output data B(1) to B(n) of the clock signal delay calculation section 7A, which are obtained by synchronizing the output signals (D(1) to (D(n)) of the delay detection circuits 10(1) to 10(n) with the falling of the reference clock signal and output from the sample-hold circuits 11(1) to 11(n), vary depending on the variations.

Hence, in the clock signal generation apparatus according to Embodiment 2, the variations in the time interval between the falling of the reference clock signal and the rising of the first output clock signal Φ1 for determining the non-overlap times due to external variation factors, such as power supply voltage and environmental temperature, can be known directly. As a result, in the clock signal generation apparatus according to Embodiment 2, the clock signal delay calculation section 7A can calculate the non-overlap times accurately, and the adjustment circuit 3 can adjust the non-overlap times to the desired non-overlap times.

In the clock signal delay calculation section 7A in the clock signal generation apparatus according to Embodiment 2, although the first output clock signal Φ1 is used as the input signal, if the output clock signal Φ1D, Φ2 or Φ2D other than the first output clock signal is used as the input signal, it is obvious that variations in the output clock signal Φ1D, Φ2 or Φ2D with respect to the reference clock signal can be known from the description of Embodiment 2. Furthermore, in the clock signal generation apparatus according to Embodiment 2, since the respective output clock signal Φ1, Φ1D, Φ2 or Φ2D is used as the input signal, the non-overlap time variations in the respective phases can be known directly by providing multiple clock signal delay calculation sections and by detecting the variations in the rising and falling times of the respective output clock signals Φ1, Φ1D, Φ2 and Φ2D.

### Embodiment 3

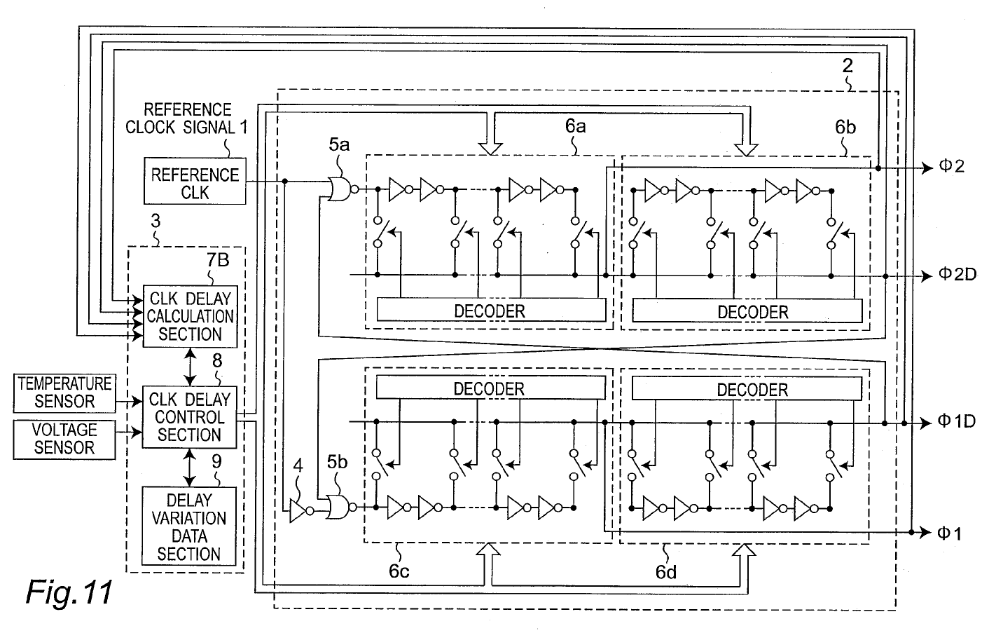

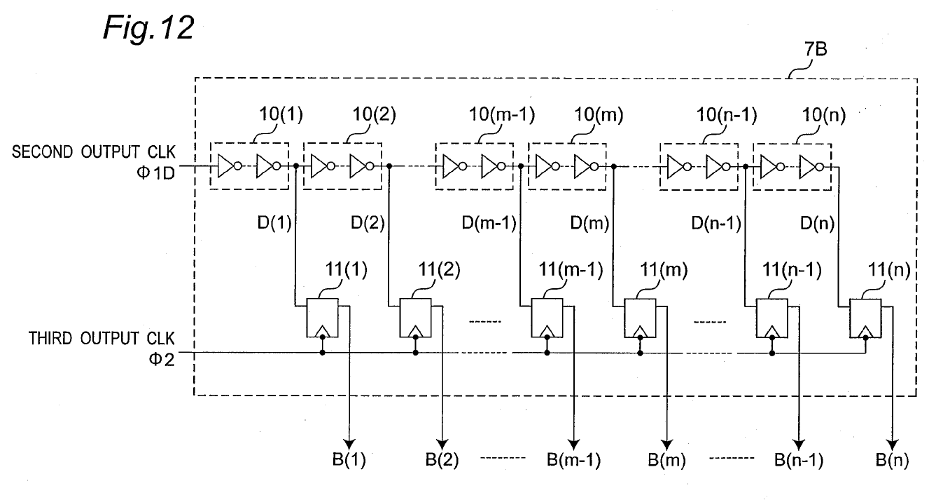

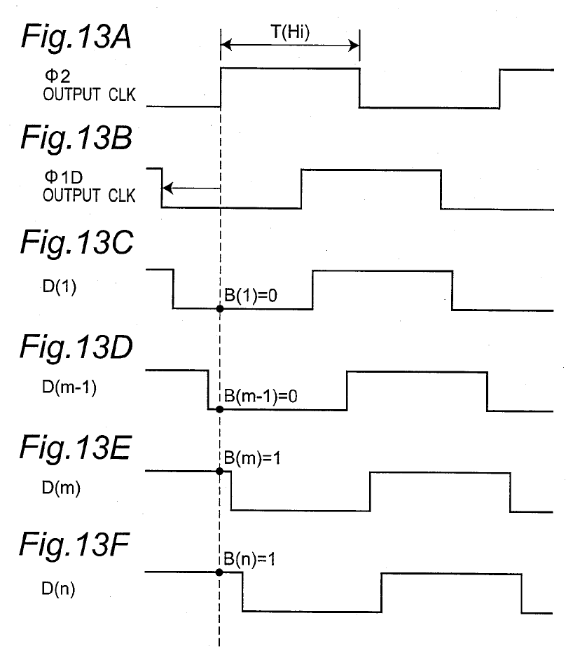

A four-phase non-overlap clock signal generator serving as a clock signal generation apparatus according to Embodiment 3 of the present invention will be described below referring to FIGS. 11 and 12 and waveform diagrams of FIGS. 13A to 13F. FIG. 11 is a block diagram showing the configuration of the clock signal generation apparatus according to Embodiment 3 of the present invention. As shown in FIG. 11, the clock signal generation apparatus according to Embodiment 3 is equipped with the clock signal generation circuit 2 and the adjustment circuit 3 as in the case of the clock signal generation apparatus according to Embodiment 1 shown in FIG. 1 described above.

The clock signal generation apparatus according to Embodiment 3 differs from the clock signal generation apparatus according to Embodiment 1 described above in that the reference clock signal from the reference clock signal generator 1 is not input to the clock signal delay calculation section 7B of the adjustment circuit 3 and that the four-phase output clock signals Φ1, Φ1D, Φ2 and Φ2D are input to the clock signal delay calculation section 7B so that the anti-phase non-overlap times in the output clock signals Φ1, Φ1D, Φ2 and Φ2D can be calculated. Hence, in the description of the clock signal generation apparatus according to Embodiment 3, the configuration and operation of the clock signal delay calculation section 7B will be described. Since the configurations and operations of the other components are the same as those of the clock signal generation apparatus according to Embodiment 1, the description in Embodiment 1 is applied, and the descriptions of the other components are omitted in the description of Embodiment 3.

FIG. 12 is a circuit diagram showing an example of the clock signal delay calculation section 7B. The clock signal delay calculation section 7B shown in FIG. 12 is provided to detect the variations in the delay amounts of the variable delay circuits 6a to 6d constituting the clock signal generation circuit 2 due to external variation factors. Hence, the clock signal delay calculation section 7B is equipped with delay devices having the same delay characteristics as those of the delay devices constituting the variable delay circuits 6a to 6d. The clock signal delay calculation section 7B is configured so that n sets of delay detection circuits 10(1) to 10(n), each being formed of a plurality of the delay devices, are connected in series. The second output clock signal Φ1D is input to the first-stage delay detection circuit 10(1), and the delay amounts of the subsequent delay detection circuits 10(2) to 10(n) are added sequentially.

Furthermore, the third output clock signal Φ2 that is in anti-phase with the second output clock signal Φ1D input to the first-stage delay detection circuit 10(1) is input to the respective sample-hold circuits 11(1) to 11(n). The respective sample-hold circuits 11(1) to 11(n) output the delay value (1 or 0) of the second output clock signal Φ1D having been input at the time as n-bit output data B(1) to B(n) in synchronization with the rising of the third output clock signal Φ2.

FIGS. 13A to 13F are waveform diagrams showing the third output clock signal Φ2 (FIG. 13A), the second output clock signal Φ1D (FIG. 13B), and the output signals D(1), D(m-1), D(m) and (D(n) output from the respective delay detection circuits 10(1), 10(m-1), 10(m) and 10(n) of the clock signal delay calculation section 7B. Herein, “n” and “m” are each a positive integer and have a relationship of 1≦m≦n. In addition, FIGS. 13C to 13F show examples of output data B(1), B(m-1), B(m) and B(n) that are held in the respective sample-hold circuits 11(1), 11(m-1), 11(m) and 11(n) in synchronization with the rising of the third output clock signal Φ2.

As shown in FIGS. 13A to 13F, in the adjustment circuit 3 according to Embodiment 3, since the second output clock signal Φ1D and the third output clock signal Φ2 are used as the input signals for detecting the delay amounts, in the output data B(1) to B(n) of the sample-hold circuits 11(1) to 11(n), the output data becomes Low (for example, B(m-1)=0) in the delay detection circuits up to the delay detection circuit 10(m-1) indicating the total delay amount that is smaller than the time interval between the rising timing of the third output clock signal Φ2 and the falling timing of the second output clock signal Φ1D. Furthermore, the output data becomes High (for example, B(m)=1) in the delay detection circuits in and after the delay detection circuit 10(m) indicating the total delay amount that is larger than the time interval between the rising timing of the third output clock signal Φ2 and the falling timing of the second output clock signal Φ1D.

For this reason, the variations in the non-overlap time of the second output clock signal Φ1D and the third output clock signal Φ2 due to external variation factors can be detected directly from the output data B(1) to B(n) of the clock signal delay calculation section 7B, which are obtained by synchronizing the output signals (D(1) to (D(n)) of the delay detection circuits 10(1) to 10(n) with the rising of the third output clock signal Φ2, output from the sample-hold circuits 11(1) to 11(n) and dependent on the variations.

Hence, in the clock signal generation apparatus according to Embodiment 3, the variations in the anti-phase non-overlap times due to external variation factors, such as power supply voltage and environmental temperature, can be known accurately. As a result, in the clock signal generation apparatus according to Embodiment 3, the clock signal delay calculation section 7B can calculate the non-overlap times accurately, and the adjustment circuit 3 can adjust the non-overlap times to the desired non-overlap times.

In the clock signal generation apparatus according to Embodiment 3, although it has been described that the second output clock signal Φ1D and the third output clock signal Φ2 are used as the input signals for the clock signal delay calculation section 7B to detect the delay amounts, in the case that the variations in the anti-phase non-overlap times are detected, the clock signal generation apparatus can also be configured so as to detect the time interval between the falling of the first output clock signal Φ1 and the rising of the fourth output clock signal Φ2D.

As described above, the clock signal generation apparatus according to Embodiment 3 may just be configured so as to detect the variations in the non-overlap time of the second output clock signal Φ1D and the third output clock signal Φ2 or to detect the variations in the non-overlap time of the first output clock signal Φ1 and the fourth output clock signal Φ2D. Furthermore, for the purpose of detecting the variations in the anti-phase non-overlap times in more detail, it is possible to detect the variations in both the anti-phase non-overlap times and to adjust the non-overlap times accurately on the basis of the result of the detection.

### Embodiment 4

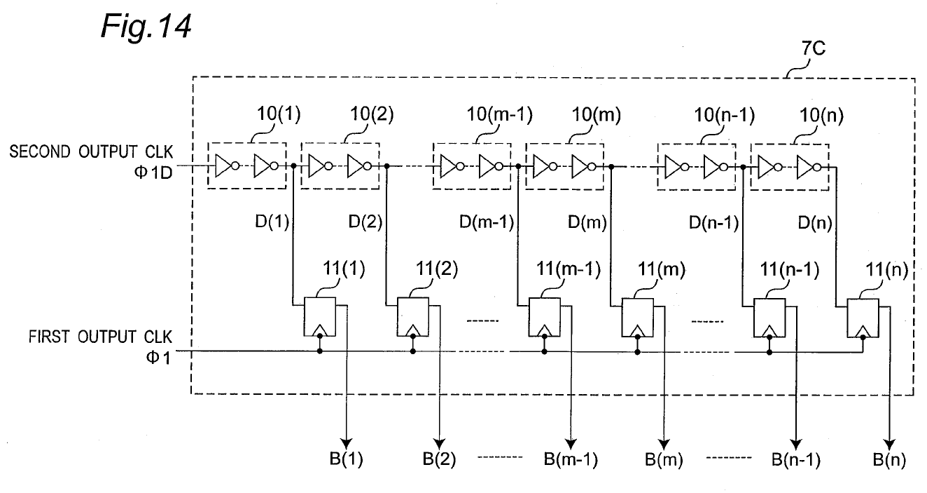

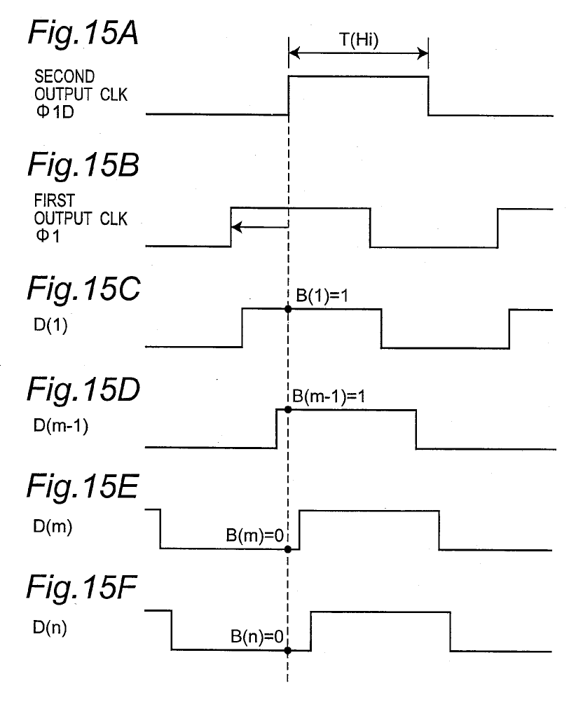

A four-phase non-overlap clock signal generator serving as a clock signal generation apparatus according to Embodiment 4 of the present invention will be described below referring to FIG. 14 and waveform diagrams of FIGS. 15A to 15F. The clock signal generation apparatus according to Embodiment 4 of the present invention is configured so as to be similar to the clock signal generation apparatus according to Embodiment 3 shown in FIG. 11 described above. In other words, the clock signal generation apparatus according to Embodiment 4 is equipped with the clock signal generation circuit 2 and the adjustment circuit 3.

The clock signal generation apparatus according to Embodiment 4 differs from the clock signal generation apparatuses according to Embodiments 1 and 3 described above in that the four-phase output clock signals Φ1, Φ1D, Φ2 and Φ2D are input to the clock signal delay calculation section 7C of the adjustment circuit 3 so that the in-phase non-overlap times in the output clock signals Φ1, Φ1D, Φ2 and Φ2D can be calculated. Hence, in the description of the clock signal generation apparatus according to Embodiment 4, the configuration and operation of the clock signal delay calculation section 7C will be described. Since the configurations and operations of the other components are the same as those of the clock signal generation apparatuses according to Embodiments 1 and 3, the descriptions in Embodiments 1 and 3 are applied, and the descriptions of the other components are omitted in the description of Embodiment 4.

FIG. 14 is a circuit diagram showing an example of the clock signal delay calculation section 7C of the adjustment circuit 3 in the clock signal generation apparatus according to Embodiment 4. The clock signal delay calculation section 7C shown in FIG. 14 is provided to detect the variations in the delay amounts of the variable delay circuits 6a to 6d constituting the clock signal generation circuit 2 due to external variation factors. Hence, the clock signal delay calculation section 7C is equipped with delay devices having the same delay characteristics as those of the delay devices constituting the variable delay circuits 6a to 6d. The clock signal delay calculation section 7C is configured so that n sets of delay detection circuits 10(1) to 10(n), each being formed of a plurality of the delay devices, are connected in series. The second output clock signal Φ1D is input to the first-stage delay detection circuit 10(1), and the delay amounts of the subsequent delay detection circuits 10(2) to 10(n) are added sequentially.

Furthermore, the first output clock signal Φ1 that is in phase with the second output clock signal Φ1D input to the first-stage delay detection circuit 10(1) is input to the respective sample-hold circuits 11(1) to 11(n). The respective sample-hold circuits 11(1) to 11(n) output the delay value (1 or 0) of the second output clock signal Φ1D having been input at the time as n-bit output data B(1) to B(n) in synchronization with the rising of the first output clock signal Φ1.

FIGS. 15A to 15F are waveform diagrams showing the second output clock signal Φ1D (FIG. 15A), the first output clock signal Φ1 (FIG. 15B), and the output signals D(1), D(m-1), D(m) and (D(n) output from the respective delay detection circuits 10(1), 10(m-1), 10(m) and 10(n) of the clock signal delay calculation section 7C. Herein, “n” and “m” are each a positive integer and have a relationship of 1≦m≦n. In addition, FIGS. 15C to 15F show examples of output data B(1), B(m-1), B(m) and B(n) that are held in the respective sample-hold circuits 11(1), 11(m-1), 11(m) and 11(n) in synchronization with the rising of the second output clock signal Φ1D.

As shown in FIGS. 15A to 15F, in the adjustment circuit 3 according to Embodiment 4, since the first output clock signal Φ1 and the second output clock signal Φ1D are used as the input signals for detecting the delay amounts, in the output data B(1) to B(n) of the sample-hold circuits 11(1) to 11(n), the output data becomes High (for example, B(m-1)=1) in the delay detection circuits up to the delay detection circuit 10(m-1) indicating the total delay amount that is smaller than the time interval between the rising timing of the first output clock signal Φ1 and the rising timing of the second output clock signal Φ1D. Furthermore, the output data becomes Low (for example, B(m)=0) in the delay detection circuits in and after the delay detection circuit 10(m) indicating the total delay amount that is larger than the time interval between the rising timing of the first output clock signal Φ1 and the rising timing of the second output clock signal Φ1D.

For this reason, the variations in the non-overlap time of the first output clock signal Φ1 and the second output clock signal Φ1D due to external variation factors can be detected accurately from the output data B(1) to B(n) of the clock signal delay calculation section 7C, which are obtained by synchronizing the output signals (D(1) to (D(n)) of the delay detection circuits 10(1) to 10(n) with the rising of the second output clock signal Φ1D and output from the sample-hold circuits 11(1) to 11(n).

With respect to the four-phase output clock signals Φ1, Φ1D, Φ2 and Φ2D, in addition to (1) the rising timing of the first output clock signal Φ1 and the rising timing of the second output clock signal Φ1D described above, (2) the rising timing of the third output clock signal Φ2 and the rising timing of the fourth output clock signal Φ2D, (3) the falling timing of the first output clock signal Φ1 and the falling timing of the second output clock signal Φ1D, and (4) the falling timing of the third output clock signal Φ2 and the falling timing of the fourth output clock signal Φ2D are available as in-phase non-overlap times.

Furthermore, with respect to the detection of the delay amounts of the non-overlap times in the above-mentioned (2) to (4), the detection is made possible by inputting the corresponding output clock signals to the clock signal delay calculation section 7C as described above. For example, in the case of detecting the delay amount of the non-overlap time in (2), a configuration may be made in which the delay amount of the rising of the third output clock signal Φ2 is detected in synchronization with the rising of the fourth output clock signal Φ2D. Moreover, in the case of detecting the delay amounts of the non-overlap times in (3) and (4), a configuration can also be made in which, in the configurations of (1) and (2), the output clock signals are input via inverters and the delay amount of the first output clock signal Φ1 or the third output clock signal Φ2 is detected in synchronization with the falling of the second output clock signal Φ1D or the fourth output clock signal Φ2D.

As a method for detecting the delay amounts of the non-overlap times in the above-mentioned (1) to (4), the non-overlap times may be adjusted on the basis of the detection of the delay amount of at least one non-overlap time, or the non-overlap times may be adjusted on the basis of the detection of the delay amounts of all the non-overlap times to further improve accuracy.

Hence, in the clock signal generation apparatus according to Embodiment 4, the variations in the in-phase non-overlap times due to external variation factors, such as power supply voltage and environmental temperature, can be known directly. As a result, in the clock signal generation apparatus according to Embodiment 4, the clock signal delay calculation section 7C can calculate the non-overlap times accurately.

### Embodiment 5

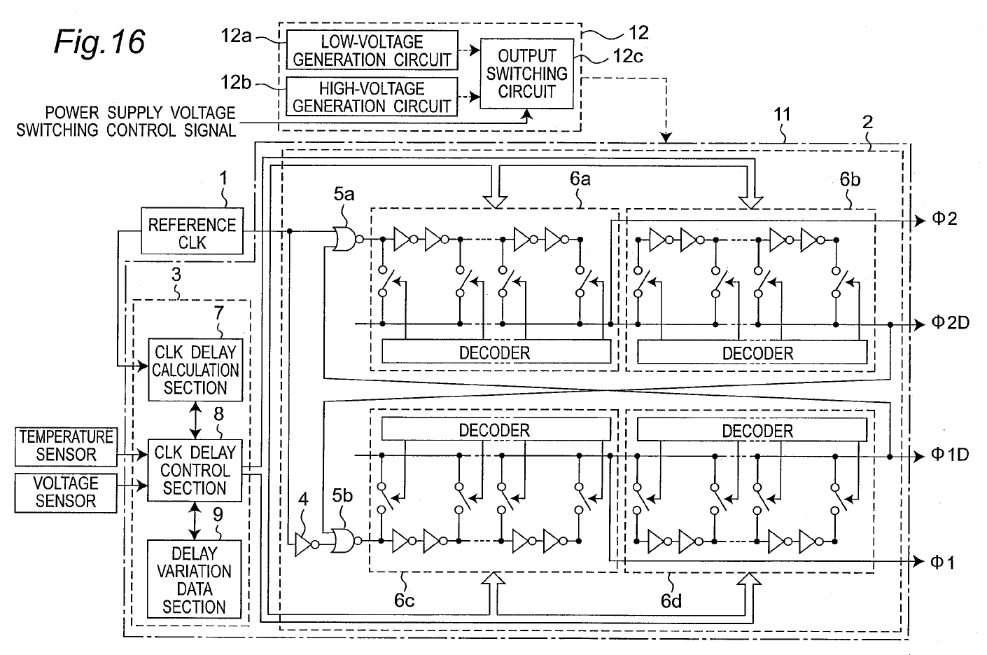

A four-phase non-overlap clock signal generator serving as a clock signal generation apparatus according to Embodiment 5 of the present invention will be described below referring to FIG. 16. FIG. 16 is a block diagram showing the configuration of the clock signal generation apparatus according to Embodiment 5. The clock signal generation apparatus according to Embodiment 5 is obtained by providing a power supply voltage switching circuit 12 for the clock signal generation apparatus according to Embodiment 1 shown in FIG. 1 described above. As shown in FIG. 16, the clock signal generation apparatus according to Embodiment 5 is equipped with the clock signal generation circuit 2, the adjustment circuit 3 and the power supply voltage switching circuit 12.

The clock signal generation apparatus according to Embodiment 5 is configured so as to detect the variations in the in-phase non-overlap times due to external variation factors, such as power supply voltage and environmental temperature, and to accurately adjust the non-overlap times as described in the clock signal generation apparatus according to Embodiment 1, and is further configured so that the power supply voltage to be input can be switched to a low-voltage mode or a high-voltage mode. The power supply voltage switching circuit 12 is equipped with a low-voltage generation circuit 12a, a high-voltage generation circuit 12b and an output switching circuit 12c and is configured so that a power supply voltage switching control signal from the CPU of an apparatus equipped with the clock signal generation apparatus is input to the output switching circuit 12c and the power supply voltage is switched to the low-voltage mode or the high-voltage mode. In the case that the power supply voltage switching circuit 12 is in the control mode in which a discrete-time circuit, such as an analog-digital converter, to which clock signals are supplied from the clock signal generation apparatus can relieve the transition times required for the rising/falling of the clock signals, the power supply voltage of the clock signal generation apparatus can be lowered and the current consumption of the clock signal generation apparatus can be reduced. In the clock signal generation apparatus according to Embodiment 5, in the case that the non-overlap times of the four-phase clock signals do not affect the characteristics of the discrete-time circuit to which the four-phase clock signals are supplied from the clock signal generation apparatus as described above, a power supply voltage corresponding to the operation mode at the time is supplied, whereby it is possible to configure an energy-saving apparatus.

Since the clock signal generation apparatus according to Embodiment 5 is configured so that the power supply voltage can be switched to the low-voltage mode or the high-voltage mode depending on the discrete-time circuit to which the output clock signals are supplied as described above, in the case that the non-overlap times of the N-phase clock signals do not affect the characteristics of the discrete-time circuit to which the output clock signals are supplied, in other words, in the case that the transition times required for the rising/falling of the output clock signals can be relieved, the power supply voltage of the clock signal generation apparatus can be lowered, and low current consumption can be attained.

The present invention provides a highly versatile apparatus serving as an N-phase non-overlap clock signal generator and capable of being applied to various appliances. In which non-overlap times required for a discrete-time circuit are variably adjusted and optimized for respective output clock signals to cope with external variation factors, such as power supply voltage and environmental temperature.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

1. A clock signal generation apparatus comprising:
a clock signal generation circuit, having n (n: a positive integer) variable delay circuits having variable delay amounts, for generating N-phase (N: a positive integer) clock signals,
a clock signal delay calculation section, having a delay detection circuit for monitoring the delay characteristics of the variable delay circuits of said clock signal generation circuit due to external variation factors, for calculating the delay amounts of the generated N-phase clock signals,
delay variation data section for previously storing the delay variation data of the non-overlap times between the respective phase output clock signals required for a discrete-time circuit to which the output clock signals from said clock signal generation circuit are supplied, and
a clock signal delay control section for varying the delay amounts of said variable delay circuits on the basis of the delay variation data, external variation factors being used as parameters thereof, stored in said delay variation data section and the delay amounts of the N-phase clock signals calculated in said clock signal delay control section.

2. The clock signal generation apparatus according to claim 1, wherein said delay detection circuit has the same delay characteristics as the delay characteristics of said variable delay circuits due to external variation factors.

3. The clock signal generation apparatus according to claim 1, wherein said clock signal delay calculation section calculates the non-overlap time between a reference clock signal and any one of the N-phase output clock signals output from said clock signal generation circuit.

4. The clock signal generation apparatus according to claim 1, wherein said clock signal delay calculation section calculates the non-overlap time between any two signals of the N-phase output clock signals output from said clock signal generation circuit.

5. The clock signal generation apparatus according to claim 1, wherein said clock signal delay control section has hysteresis between the switching standard for increasing the delay amount and the switching standard for decreasing the delay amount in the control signals to be output to said clock signal generation circuit.

6. The clock signal generation apparatus according to claim 1, wherein said clock signal delay control section averages said control signals to be output to said clock signal generation circuit with a preset average number and outputs the averaged control signal.

7. The clock signal generation apparatus according to claim 1, wherein power supply voltage is switched between a low-voltage mode or a high-voltage mode depending on a discrete-time circuit to which the output clock signals are supplied.

8. The clock signal generation apparatus according to claim 1, wherein said clock signal delay calculation section, said clock signal delay control section and said delay variation data section are ON/OFF controlled using control signals from the outside of said apparatus.

9. The clock signal generation apparatus according to claim 1, wherein said clock signal delay calculation section has initial data serving as reference to be input to said delay detection circuit and outputs the relative variation amount between said initial data and the data output from said delay detection circuit.

10. A discrete-time circuit equipped with said clock signal generation apparatus according to claim 1.

11. A discrete-time circuit equipped with said clock signal generation apparatus according to claim 2.

12. A discrete-time circuit equipped with said clock signal generation apparatus according to claim 3.

13. A discrete-time circuit equipped with said clock signal generation apparatus according to claim 4.

14. A discrete-time circuit equipped with said clock signal generation apparatus according to claim 5.

15. A discrete-time circuit equipped with said clock signal generation apparatus according to claim 6.

16. A discrete-time circuit equipped with said clock signal generation apparatus according to claim 7.

17. A discrete-time circuit equipped with said clock signal generation apparatus according to claim 8.

18. A discrete-time circuit equipped with said clock signal generation apparatus according to claim 9.
